(19) United States
(12) Patent Application Publication
(10) Pub. No.: US 2009/0298300 A1
(43) Pub. Date: Dec. 3, 2009

(54) Apparatus and Methods for Hyperbaric Rapid Thermal Processing

(75) Inventors: Joseph M. Ranish, San Jose, CA (US); Khurshed Sorabji, San Jose, CA (US); Alexander N. Lerner, San Jose, CA (US); Aaron M. Hunter, Santa Cruz, CA (US)

Correspondence Address: DIEHL SERVILLA LLC, 77 BRANT AVENUE, SUITE 210, CLARK, NJ, 07066, US

(73) Assignee: Applied Materials, Inc., Santa Clara, CA (US)

(21) Appl. No.: 12/437,257

(22) Filed: May 7, 2009

Related U.S. Application Data
(60) Provisional application No. 61/051,889, filed on May 9, 2008.

(51) Int. Cl. H01L 21/324; H01L 21/67

(52) U.S. Cl. 438/795; 392/416; 257/E21.328

(57) ABSTRACT

Methods and apparatus for hyperbaric rapid thermal processing of a substrate are described. Methods of processing a substrate in a rapid thermal processing chamber are described that include passing a substrate from outside the chamber through an access port onto a support in the interior region of the processing chamber, closing a port door sealing the chamber, pressurizing the chamber to a pressure greater than 1.5 atmospheres absolute and directing radiant energy toward the substrate. Hyperbaric rapid thermal processing chambers are described which are constructed to withstand pressures greater than at least about 1.5 atmospheres absolute or, optionally, 2 atmospheres of absolute pressure. Processing chambers may include pressure control valves to control the pressure within the chamber.

### CROSS-REFERENCE TO RELATED APPLICATIONS

This application claims the benefit of U.S. provisional patent application Ser. No. 61/051,889, filed on May 9, 2008, the entire content of which is incorporated herein by reference.

### TECHNICAL FIELD

This invention relates generally to thermal processing of substrates. In particular, embodiments of the invention relate to rapid thermal processing of semiconductor substrates at super-atmospheric pressures.

### BACKGROUND

Rapid thermal processing (RTP) is a well-developed technology for fabricating semiconductor integrated circuits in which the substrate, for example, a silicon wafer, is irradiated with high-intensity optical radiation in a RTP chamber to quickly heat the substrate to a relatively high temperature to thermally activate a process in the substrate. Once the substrate has been thermally processed, the radiant energy is removed and the substrate quickly cools. As such, RTP is energy efficient because the chamber surrounding the substrate is not heated to the elevated temperatures required to process the substrate, and only the substrate is heated. In other words, during rapid thermal processing, the processed substrate is not in thermal equilibrium with the surrounding environment, namely the chamber.

The fabrication of integrated circuits from silicon or other wafers involves many steps of depositing layers, photolithographically patterning the layers, and etching the patterned layers. Ion implantation is used to dope active regions in the semiconductive silicon. The fabrication sequence also includes thermal annealing of the wafers for many uses including curing implant damage and activating the dopants, crystallization, thermal oxidation and nitridation, silicidation, chemical vapor deposition, vapor phase doping, and thermal cleaning, among others.

Although annealing in early stages of silicon technology typically involved heating multiple wafers for long periods in an annealing oven, RTP has been increasingly used to satisfy the ever more stringent requirements for processing substrates with increasingly smaller circuit features. RTP is typically performed in single-wafer (or substrate) chambers by irradiating a wafer with light from an array of high-intensity lamps directed at the front face of the wafer on which the integrated circuits are being formed. The radiation is at least partially absorbed by the wafer and quickly heats it to a desired high temperature, for example above 600° C., or in some applications above 1000° C. The radiant heating can be quickly turned on and off to controllably heat the wafer over a relatively short period, for example, one minute or, for example, 30 seconds, more specifically, 10 seconds, and even more specifically, one second. Temperature changes in RTP chambers are capable of occurring at rates of at least about 25° C. per second to 50° C. per second and higher, for example at least about 100° C. per second or at least about 150° C. per second.

During the processing of a substrate in a RTP chamber, contaminants build up on the internal surfaces of the chamber. The contamination arises from substances deposited on or instrinsic to the wafer and can include compounds of silicon, boron, arsenic, phosphorous and others. This contaminant buildup results in the need to clean the internal surfaces of the chamber. The internal surfaces include pyrometer probes, reflector plate and quartz window covering the lamp surfaces. While the chamber is being cleaned, it cannot be used to process additional substrates, resulting in a loss of productivity. Therefore, a need exists in the art for methods and apparatus to prolong the period of time between chamber cleanings.

### SUMMARY

According to an embodiment of the invention, methods and apparatus are provided for rapid thermal processing of substrates, for example, semiconductor substrates in a processing chamber at pressures in excess of at least about 1.5 atmospheres absolute or, optionally, 2 atmospheres absolute. As used herein, the phrase “absolute pressure” refers to the pressure of the gas in the processing volume and may be used interchangeably with the phrase “internal pressure” or “internal chamber pressure.”

In one embodiment, the methods and apparatus described herein are intended to prolong the period of time between chamber cleanings by decreasing the diffusivity of contaminant species. The decrease in contaminant diffusivity is typically a function of gas absolute pressure. According to one or more embodiments, increasing the internal pressure of an inert gas within a RTP chamber will cause a decrease of the diffusivity of contaminant species which may be released by the high temperature processes.

Embodiments of the invention are directed to a method of processing a substrate in a RTP chamber, which comprises passing a substrate from outside the RTP chamber through an access port onto an annular support located in an interior region of the processing chamber, closing the access port so that the RTP chamber is isolated from ambient air, pressurizing the RTP chamber to a pressure greater than about 1.5 atmospheres absolute or, optionally, 2 atmospheres absolute; and directing radiant energy towards the substrate to controllably and uniformly heat the substrate at a rate of at least about 50° C. per/second. In one embodiment, the RTP chamber is pressurized to greater than about 5 atmospheres absolute. In another embodiment, the RTP chamber is pressurized between about 1.5 atmospheres absolute or, optionally, 2 atmospheres absolute and about 5 atmospheres absolute. In still another embodiment, the RTP chamber is pressurized between about 1.5 atmospheres absolute or, optionally, 2 atmospheres absolute and about 10 atmospheres absolute. Exemplary pressures at which the processing chamber may be pressurized include pressures up to about 2.5, 3, 3.5, 4, 4.5 or 5 atmospheres absolute. In one embodiment, the method also includes rapid thermal annealing of the substrate, which may be a semiconductor substrate.

One or more aspects of the present invention include a method of processing a substrate in a RTP chamber, which may include rapid thermal annealing. In one or more embodiments, the method of processing a substrate in a RTP chamber includes passing a substrate from outside the RTP chamber through an access port onto an annular support located in an interior region of the processing chamber and closing the access port so that the RTP chamber is sealed. As used in this application, the term “sealed” shall include isolating the chamber from air that has a reduced pressure than the pressure within the processing chamber. The term “sealed” also includes isolating the chamber from air, air outside of the chamber, and/or transfer chamber atmosphere.

In one or more embodiments of the invention, after the chamber is sealed, the method further includes pressurizing the RTP chamber to a pressure greater than about 1.5 atmospheres absolute and directing radiant energy towards the substrate to controllably and uniformly heat the substrate at a rate of at least about 50° C. per/second. In a specific embodiment, the method includes pressurizing the RTP chamber to an absolute pressure in the range of about 1.5 atmospheres absolute or, optionally, 2 atmospheres to about 5 atmospheres. In a more specific embodiment of the method, the RTP chamber is pressurized to an absolute pressure up to about 2.5, 3, 3.5, 4 or 4.5 atmospheres.

One or more embodiments of the methods described herein of processing a substrate in an RTP chamber utilize substrates such as semiconductor wafers. The chamber utilized in one or more embodiments may also include a radiant heat source and a disc shaped surface between the chamber and the radiant heat source. In one or more embodiments, the disc shaped surface is constructed or designed to withstand at least about 1.5 atmospheres absolute or, optionally, 2 atmospheres of absolute pressure. In a more specific embodiment, the disc shaped surface is constructed to withstand pressures in the range of about 1.5 atmospheres absolute or, optionally, 2 atmospheres absolute to about at pressures up to about 2.5, 3, 3.5, 4, 4.5 or 5 atmospheres absolute, and may withstand such pressures while the substrate is processed. The chamber may also include a reflector plate disposed opposite the radiant heat source that is constructed or designed to withstand at least 1.5 atmospheres absolute or, optionally, 2 atmospheres of absolute pressure and/or, alternatively, at pressures up to about 2.5, 3, 3.5, 4, 4.5 or 5 atmospheres absolute.

A second aspect of the present invention pertains to a RTP chamber, which may be a cold wall reactor type, that includes a chamber body defining a chamber volume, a substrate support for supporting a substrate within the chamber for processing, a first heat source that heats the substrate and a pressure control valve to control pressure within the chamber. In one or more embodiments, the substrate support is magnetically coupled to a stator.

The pressure control valve utilized in one or more embodiments includes a back pressure regulator and a pressure controller. The pressure control valve of one or more embodiments controls or maintains the pressure within the chamber in excess of 1.5 atmospheres absolute or, optionally, 2 atmospheres absolute. The pressure control valve utilized in one or more embodiments may control or maintain pressure within the chamber in the range of about 1.5 atmospheres absolute or, optionally, 2 atmospheres absolute to about 5 atmospheres absolute. In specific embodiments, the pressure control valve is operative to control or maintain pressure within the chamber up to 2.5, 3, 3.5 atmospheres absolute, 4 atmospheres absolute and 4.5 atmospheres absolute, respectively.

In one embodiment, the chamber comprises a disc shaped surface between the processing volume and radiant heat source. The disc shaped surface may be constructed to withstand at least about 1.5 or 2 atmospheres of absolute pressure. In one or more embodiments, the disc shaped surface located between the heat source and processing volume forms a window, which, if made thick enough, could support or withstand pressure gradient within the processing volume. In one or more embodiments, the disc shaped surface may be supported by the heat source housing, for example, a lamphead housing, and is constructed and/or designed to withstand pressure gradient. In another embodiment, the disc shaped surface is constructed to withstand pressures up to about 10 atmospheres absolute. In one embodiment, the chamber comprises a reflector plate located opposite the radiant heat source, that is constructed to withstand at least 1.5 atmospheres absolute or, optionally, 2 atmospheres of absolute pressure. In still another embodiment, the reflector plate is constructed to withstand pressures up to about 10 atmospheres absolute. Pressures up to about 2.5, 3, 3.5, 4, 4.5 or 5 atmospheres absolute are exemplified.

### BRIEF DESCRIPTION OF THE DRAWINGS

FIG. 1 shows a cross-sectional view of a RTP chamber according to one or more embodiments; and

FIG. 2 illustrates a simplified isometric view of a RTP chamber according to one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Embodiments of the present invention provide methods and apparatus for an improved RTP chamber. Examples of RTP chambers that may be adapted to benefit from the invention are the “Applied Vantage RadiancePlus RTP” and CENTURA® thermal processing systems, both available from Applied Materials, Inc. of Santa Clara, Calif. It will be appreciated that while specific embodiments are shown in the Figures related to what may be referred to “cold wall reactors” in which the temperature of the walls of the processing chamber is less than the temperature of the substrate being processed, according to embodiments of the invention, processing wafers at chamber internal pressures in excess of atmospheric pressure, for example, absolute pressure exceeding 1 atmosphere, exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres can be applied to chambers having other types of heating and cooling systems. For example, the processing methods described herein will have utility in conjunction with heating/cooling systems employing inductive or resistive heating. In addition, although the specific embodiments for the present invention are illustrated with reference primarily to RTP, one skilled in the art will understand that chemical vapor deposition (CVD) would also be suitable. Thus according to one or more embodiments of the present invention, methods and apparatus are provided for rapid thermal processing of substrates in any type of RTP chamber at chamber internal pressures in excess of atmospheric pressure, for example, absolute pressure exceeding 1 atmosphere, exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres.

According to one or more embodiments of the invention, operating a RTP chamber at pressures in excess of 1.5 atmospheres absolute or, optionally, 2 atmospheres absolute increases the period of time between chamber cleanings. Increasing absolute pressure within the processing chamber is achieved by increasing the pressure of an inert gas or process gas within the RTP chamber, which will result in a decrease of the diffusivity of contaminant species which may be released by high temperature processes. In the case of a process gas, the increased pressure may also enable higher rates of reaction at the substrate surface or within the gas phase.

Since the diffusivity of the contaminants varies approximately inversely with the total pressure or the absolute pressure, a doubling of the absolute pressure should result in a doubling of the period between cleanings of chamber components including pyrometer probes, reflector plates and lamp surfaces, for example a lamphead window. For modest pressure increases, buoyancy effects will be small and possibly could be used to help direct the deposition to less critical regions.

RTP normally operates at pressures between 0.007 atmospheres to 1.05 atmospheres (5 and 800 torr). As such, RTP chambers, including the internal components, have been designed to operate under sub-atmospheric or near atmospheric conditions. To operate at pressures greater than atmospheric, and in particular, exceeding 1.5 atmospheres absolute or, optionally, 2 atmospheres absolute, the access ports, disc areas of the reflector plate and lamphead, rotor well and side walls, and other fixtures described further below may need to be reinforced. For example, the valve or access port between the chamber and the wafer supply, which allows the wafer to pass through to the interior of the chamber, is modified to operate under super-atmospheric pressures. Embodiments of the invention provide a RTP chamber constructed to withstand internal pressures greater than atmospheric, and in particular, in excess of 1.5 atmospheres absolute or, optionally, 2 atmospheres absolute. In certain cold wall chambers, a redesign of the access port that allows the wafer to pass from the wafer supply to the interior of the chamber may be required. Such redesign can be accomplished either by strengthening the retaining fixturing on the outside of the valve or by repositioning the valve so that the O-ring sealing face is on the inside and pressed against the sealing face of the chamber side wall by the internal pressure. According to one or more embodiments, other portions of the RTP chamber, including the disc area of the reflector place and the disc area of the lamphead are fortified to withstand pressures in excess of about 1.5 atmospheres absolute or, optionally, 2 atmospheres absolute. Backing plates may be used to provide additional stiffening of the lamphead and/or the reflector plate. Thicker material or higher strength alloys may be used in the construction of the rotor well and side walls. Higher pressure rated bellows with side constraints may be used in the lift pin assemblies, and the integrity of the lightpipe-reflector plate seal may be reinforced mechanically to prevent higher internal pressure from displacing the optical pipe.

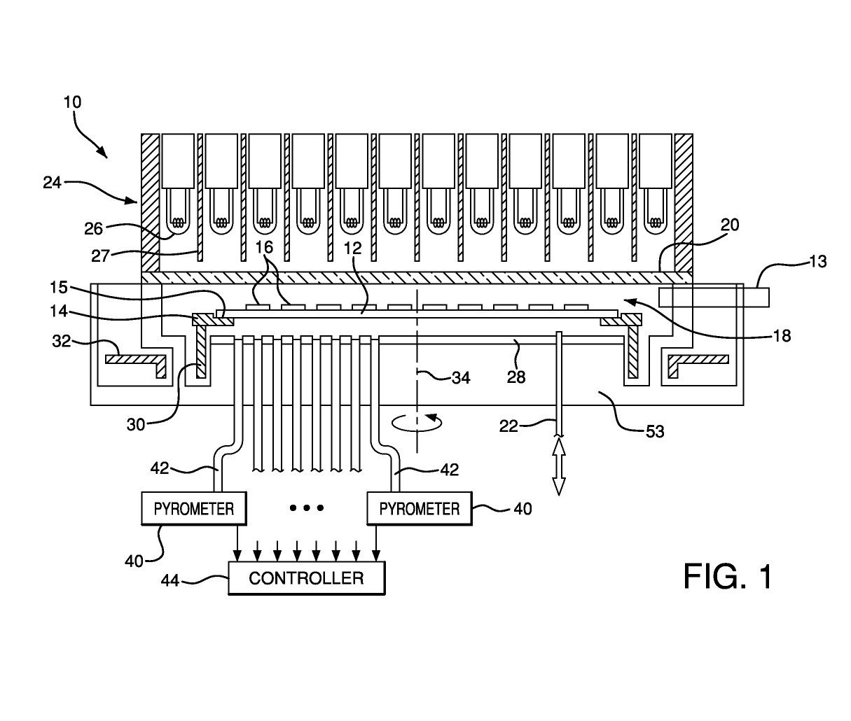

FIG. 1 schematically represents a RTP chamber 10. Peuse et al. describe further details of this type of reactor and its instrumentation in U.S. Pat. Nos. 5,848,842 and 6,179,466. A wafer or substrate 12, for example a semiconductor wafer such as a silicon wafer to be thermally processed is passed through the valve or access port 13 into the process area 18 of the chamber 10. The wafer 12 is supported on its periphery by a substrate support in the form of an annular edge ring 14 having an annular sloping shelf 15 contacting the corner of the wafer 12. Ballance et al. more completely describe the edge ring and its support function in U.S. Pat. No. 6,395,363. The wafer is oriented such that processed features 16 already formed in a front surface of the wafer 12 face upwardly, referenced to the downward gravitational field, toward a process area 18 defined on its upper side by a transparent quartz window 20. Contrary to the schematic illustration, the features 16 for the most part do not project substantial distances beyond the surface of the wafer 12 but constitute patterning within and near the plane of the surface. The nature of the wafer features 16 is multi-faceted and will be discussed later. Lift pins 22 may be raised and lowered to support the back side of the wafer 12 when the wafer is handed between a paddle or robot blade (not shown) bringing the wafer into the chamber and onto the edge ring type substrate support 14. A radiant heating apparatus 24 is positioned above the window 20 and the substrate support 14 to direct radiant energy toward the wafer 12 and thus to heat it. In the chamber 10, the radiant heating apparatus includes a large number, 409 being an exemplary number, of high-intensity tungsten-halogen lamps 26 positioned in respective reflective hexagonal tubes 27 arranged in a close-packed which extends down and supports the window 20 against internal chamber pressure.

The array of lamps 26 is sometimes referred to as the lamphead. In one or more embodiments the lamphead assembly has a stiffniess that prevents deformation axially in an amount greater than about 0.010 inch under the increased pressure in the chamber of up to about 5 atmospheres absolute. The stiffniess of the lamphead assembly can be increased by increasing the overall thickness of the lamphead or by using a higher strength alloy metal to withstand the increased pressure in the chamber. In one or more alternative embodiments, backing plates may be utilized to provide additional stiffness to the lamphead. Such material or dimensional changes can be determined experimentally and/or by finite element modeling. Other radiant heating apparatus may be substituted. Generally, these involve resistive heating to quickly ramp up the temperature of the radiant source.

As used herein, RTP refers an apparatus or a process capable of uniformly heating a wafer at rates of about 50° C./second and higher, for example, at rates of 100° C./second to 150° C./second, and 200° C./second to 400° C./second. Typical ramp-down (cooling) rates in RTP chambers are in the range of 80° C./second to 150° C./second. Some processes performed in RTP chambers require variations in temperature across the substrate of less than a few degrees Celsius. Thus, an RTP chamber must include a lamp or other suitable heating system and heating system control capable of heating at rate of up to 100° C./second to 150° C./second, and 200° C./second to 400° C./second distinguishing RTP chambers from other types of thermal chambers that do not have a heating system and heating control system capable of rapidly heating at these rates.

It is important to control the temperature across the wafer 12 to a closely defined temperature uniform across the wafer 12. One passive means of improving the uniformity includes a reflector 28 extending parallel to and over an area greater than the wafer 12 and facing the back side of the wafer 12. The reflector 28 efficiently reflects heat radiation emitted from the wafer 12 back toward the wafer 12. The spacing between the wafer 12 and the reflector 28 is preferably within the range of 3 to 9 mm, and the aspect ratio of the width to the thickness of the cavity is advantageously greater than 20. The reflector 28, which may be formed of a gold coating or multi-layer dielectric interference mirror, effectively forms a black-body cavity at the back of the wafer 12 that tends to distribute heat from warmer portions of the wafer 12 to cooler portions. In other embodiments, for example, as disclosed in U.S. Pat. Nos. 6,839,507 and 7,041,931, the reflector 28 may have a more irregular surface or have a black or other colored surface to more closely resemble a black-body wall. The black-body cavity is filled with a distribution, usually described in terms of a Planck distribution, of radiation corresponding to the temperature of the wafer 12 while the radiation from the lamps 26 has a distribution corresponding to the much higher temperature of the lamps 26. Preferably, the reflector 28 is deposited on a water-cooled base to heat sink excess radiation from the wafer, especially during cool down.

One way of improving the uniformity includes supporting the edge ring 14 on a rotatable cylinder 30 that is magnetically coupled to a rotatable flange 32 positioned outside the chamber. A motor (not shown) rotates the flange 32 and hence rotates the wafer about its center 34, which is also the centerline of the generally symmetric chamber.

Another way of improving the uniformity divides the lamps 26 into zones arranged generally ring-like about the center 34. Control circuitry varies the voltage delivered to the lamps 26 in the different zones to thereby tailor the radial distribution of radiant energy. Dynamic control of the zoned heating is effected by, a plurality of pyrometers 40 coupled through optical light pipes 42 positioned to face the back side of the wafer 12 through apertures in the reflector 28 to measure the temperature across a radius of the rotating wafer 12. The light pipes 42 may be formed of various structures including sapphire, metal, and silica fiber. A computerized controller 44 receives the outputs of the pyrometers 40 and accordingly controls the voltages supplied to the different rings of lamps 26 to thereby dynamically control the radiant heating intensity and pattern during the processing. Pyrometers generally measure light intensity in a narrow wavelength bandwidth of, for example, 40 nm in a range between about 700 to 1000 nm. The controller 44 or other instrumentation converts the light intensity to a temperature through the well known Planck distribution of the spectral distribution of light intensity radiating from a black-body held at that temperature. Pyrometry, however, is affected by the emissivity of the portion of the wafer 12 being scanned. Emissivity ε can vary between 1 for a black body to 0 for a perfect reflector and thus is an inverse measure of the reflectivity R=1−ε of the wafer back side. While the back surface of a wafer is typically uniform so that uniform emissivity is expected, the backside composition may vary depending upon prior processing. The pyrometry can be improved by further including a emissometer to optically probe the wafer to measure the emissivity or reflectance of the portion of the wafer it is facing in the relevant wavelength range and the control algorithm within the controller 44 to include the measured emissivity.

In the embodiment shown in FIG. 1, the separation between the substrate 12 and the reflector 28 is dependent on the desired thermal exposure for the given substrate 12. In one embodiment, the substrate 12 can be disposed at a greater distance from the reflector 28 to increase the amount of thermal exposure to the substrate. In another embodiment, the substrate 12 can be placed closer to the reflector 28 to decrease the amount of thermal exposure to the substrate 12. The exact position of the substrate 12 during the heating of the substrate 12 and the residence time spent in a specific position depends on the desired amount of thermal exposure to the substrate 12.

In another embodiment, when the substrate 12 is in a lower position, proximate the reflector 28, the thermal conduction from the substrate 12 to the reflector 28 increases and enhances the cooling process. The increased rate of cooling in turn promotes optimal RTP performances. The closer the substrate 12 is positioned to the reflector 28; the amount of thermal exposure will proportionally decrease. The embodiment shown in FIG. 1 allows the substrate 12 support to be easily levitated at different vertical positions inside the chamber to permit control of the substrate's thermal exposure.

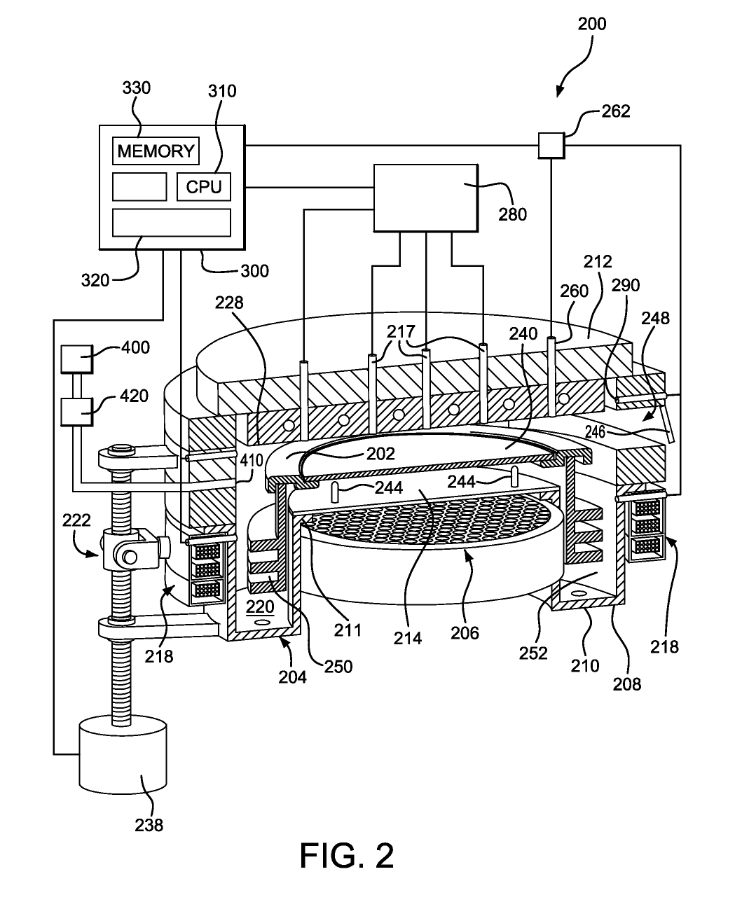

An alternative embodiment of an RTP chamber 200 is shown in FIG. 2. It will be appreciated from a comparison of FIG. 1 and FIG. 2, that in FIG. 2, the positioning of the lamphead 206 (in FIG. 2) with respect to the substrate support 202 is reversed from the configuration shown in FIG. 1. In other words, the lamphead 206 in FIG. 2 is positioned beneath the substrate support, which permits substrates having features such as die already formed in a front surface of the wafer to face upwardly and to have the back side of the substrate that does not contain features such as die to be heated. In addition, the components redesigned to handle the increased chamber pressure and discussed above with respect to FIG. 1 can be used in a chamber of the type shown in FIG. 2. Likewise, components redesigned to handle the increased chamber pressure and discussed with respect to FIG. 2 can used in a chamber of the type shown in FIG. 1. In FIG. 2, the processing chamber 200 includes a substrate support 202, a chamber body 204, having walls 208, a bottom 210, and a top 212 and a reflector plate 228 defining an interior volume 220. In one or more embodiments of the chamber, the bottom 210 of the chamber has a stiffness that prevents deformation axially in an amount greater than about 0.010 inches under chamber pressure up to about 5 atmospheres absolute. This can be accomplished by reinforcing a conventional chamber, such as providing a thicker chamber wall or by using stronger materials for the construction of the wall. Suitable materials and wall thickness can be determined empirically and or by finite element modeling.

The reflector plate 228 located opposite the radiant heat source may be constructed to withstand at least 2 atmospheres absolute. Detailed embodiments are constructed such that the reflector plate can withstand absolute pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres. An alternative embodiment has a reflector plate constructed to withstand absolute pressure up to and exceeding 10 atmospheres absolute.

The walls 208 typically include at least one substrate access port 248 to facilitate entry and egress of a substrate 240 (a portion of which is shown in FIG. 2). The access port 248 may be coupled to a transfer chamber (not shown) or a load lock chamber (not shown) and may be selectively sealed with a slit valve having a sealing door 246. The valve 410 may be connected to a pressure control 400 and a pressure regulator 420. In one or more embodiments, the pressure control valve is designed to control the pressure within the chamber in the range from about 1 atmosphere absolute up to and including about 5 atmospheres absolute. In specific embodiments, the pressure control valve is designed to control the absolute pressure within the pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres.

An example of a suitable control scheme and device for controlling the absolute pressure within the chamber at higher pressures than in conventional processing would be to deliver the gas at a specified delivery pressure at the ranges/values described immediately above. A suitable flow controller delivers gas into the chamber until the absolute pressure in the chamber reaches the desired value. A suitable back pressure regulator 420, for example any suitable spring load, dome load, or air load regulator for regulating pressure to a desired value or range can be utilized. An example of a suitable regulator is a Tescom 26-2300 regulator, available from Tescom of Elk River, Minn. An example of a suitable flow controller is an ER3000 series electronic pressure controller, also available from Tescom.

The door 246 is also able to withstand a force exerted from within the chamber in an amount in the range of exceeding about 1 atmosphere absolute up to and in excess of about 5 atmospheres absolute. For example, the door 246 is designed to withstand the absolute pressure within the pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres. A suitable door can be designed using finite element modeling.

The chamber 200 also includes a window 214 made from a material transparent to heat and light of various wavelengths, which may include light in the infra-red (IR) spectrum, through which photons from the radiant heat source 206 may heat the substrate 240. In the embodiment shown in FIG. 2, the bottom 210 includes a flange 211 that extends between the window 214 and the lamphead 206, creating a gap between the window 214 and the lamphead 206. In an alternative embodiment, the lamphead 206 may include a recess (not shown) to accommodate the flange 211 or the flange 211 can be eliminated so that the window 214 can be supported over a majority of its surface by the lamphead 206. Thus, in such embodiments in which there is a recess to receive the window or there is no flange 211, it will be appreciated that no gap or space between the lamphead 206 and the window 214. In one embodiment, the window 214 is made of a quartz material, although other materials that are transparent to light may be used, such as sapphire. The window 214 may also include a plurality of lift pins 244, which function as a temporary support structure. The lift pins 244 are coupled to an upper surface of the window 214, which are adapted to selectively contact and support the substrate 240, to facilitate transfer of the substrate into and out of the chamber 200.

In one embodiment, the radiant heat source 206 provides sufficient radiant energy to thermally process the substrate, for example, annealing a silicon layer disposed on the substrate 240. Dynamic control of the heating of the substrate 240 may be affected by the one or more temperature sensors 217, for example, optical pyrometers, adapted to measure the temperature across the substrate 240. The one or more temperature sensors 217, which may be adapted to sense temperature of the substrate 240 before, during, and after processing. In the embodiment depicted in FIG. 2, the temperature sensors 217 are disposed through the chamber top 212, although other locations within and around the chamber body 204 may be used. The temperature sensors 217 may be optical pyrometers, as an example, pyrometers having fiber optic probes and may be connected to a sensor control 280.

The chamber 200 may also include a gas inlet 260 and a gas outlet (not shown) for introducing gas into the chamber and/or for maintaining the chamber within a preset pressure range. In one or more embodiments, a gas can be introduced into the interior volume 220 of the chamber through a gas inlet 260 for reaction with the substrate 240. Once processed, the gas can be evacuated from the chamber using gas outlet (not shown). The gas inlet includes a gas inlet control valve 262 which controls the flow rate of gases entering the chamber through the gas inlet 260. The gas inlet control valve 262 operates at pressures in a range exceeding about 1 atmosphere absolute up to and exceeding about 5 atmospheres absolute. For example, the gas inlet control valve 262 is designed to control the gas flow rate to the processing volume which is maintained at an absolute pressure within the pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres. It will be appreciated that the chamber may include a plurality of gas inlets and control valves to allow the flow of more than one gas into the chamber.

In the embodiment shown in FIG. 2, a stator assembly 218 circumscribes the walls 208 of the chamber body 204 and is coupled to one or more actuator assemblies 222 that control the elevation of the stator assembly 218 along the exterior of the chamber body 204. The stator assembly 218 may be magnetically coupled to the substrate support 202 disposed within the interior volume 220 of the chamber body 204. The substrate support 202 may comprise or include a rotor system 250, which creates a magnetic bearing assembly to lift and/or rotate the substrate support 202. The rotor system 250 may include a rotor well bounded by rotor well wall 252. The rotor well wall may be formed or constructed using thicker materials or higher strength alloys, which can be determined empirically and/or by finite element modeling. Similarly, the chamber side walls 208 may also be constructed from thicker materials and/or materials having higher strength, such as higher strength alloys. In one or more embodiments, the outer diameter of the rotor well wall 252 is constructed to deform radially less than about 0.001 inch under chamber pressures up to about 5 atmospheres absolute. Alternatively, the rotor wall may be fortified with an auxiliary material that does not interfere with the function of the rotor, for example, a high strength epoxy or cement.

In one embodiment, a motor 238, such as a stepper or servo motor, is coupled to the actuator assembly 222 to provide controllable rotation in response to a signal by the controller 300. Alternatively, other types of actuators 222 may be utilized to control the linear position of the stator 218, such as pneumatic cylinders, hydraulic cylinders, ball screws, solenoids, linear actuators and cam followers, among others.

The chamber 200 also includes a controller 300, which generally includes a central processing unit (CPU) 310, support circuits 320 and memory 330. The CPU 340 may be one of any form of computer processor that can be used in an industrial setting for controlling various actions and sub-processors. The memory 330, or computer-readable medium, may be one or more of readily available memory such as random access memory (RAM), read only memory (ROM), floppy disk, hard disk, or any other form of digital storage, local or remote, and is typically coupled to the CPU 310. The support circuits 320 are coupled to the CPU 310 for supporting the controller 300 in a conventional manner. These circuits include cache, power supplies, clock circuits, input/output circuitry, subsystems, and the like.

In one or more embodiments, any flanges that are present in the chamber are capable of withstanding a force generated by internal processing volume pressures in the range from about 2 atmospheres absolute to about 5 atmospheres absolute pressure. In a specific embodiment, the one or more of the flanges may withstand a force exerted from within the chamber the flanges are designed to withstand absolute pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres.

In one or more embodiments, all of the components of the chamber 200 operate at conditions in which the pressure in the interior volume 220 is in the range exceeding from about 1 atmosphere absolute up to and exceeding about 5 atmospheres absolute. In a specific embodiment, the components may include o-ring seal structures which function at conditions in which the pressure in the interior volume 220 is in the range from about 1 atmosphere absolute to about 5 atmospheres absolute. One or more examples of chamber 200 include a view port 290, from which the progress of the RTP process can be viewed. The view port may include a retainer (not shown). In one or more embodiments, the view port and/or the retainer withstand pressures within the interior volume 220 of the chamber in the range from about 2 atmospheres absolute up to and exceeding about 5 atmospheres absolute. In general, the components of the chamber are designed to withstand absolute pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres.

For example, according to other embodiments, the chamber further comprises a disc shaped surface between the chamber processing volume and radiant heat source, the disc shaped surface constructed to withstand at least about 2 atmospheres of absolute pressure. A detailed embodiment has the disc shaped surface constructed to withstand absolute pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres. An alternative embodiment has a disc shaped surface constructed to withstand absolute pressure up to and exceeding 10 atmospheres absolute.

One or more embodiments of the invention are directed toward methods of processing a substrate. A substrate is passed through the valve or access port into a RTP chamber. The access port is closed to isolate the chamber interior from the outside environment and ambient air. The substrate is placed onto a support structure which is located within the RTP chamber. Radiant energy is directed toward the substrate to controllably heat the substrate at a rate of at least about 50° C./second. The radiation is at least partially absorbed by the wafer and quickly heats it to a desired high temperature, for example above 600° C., or in some applications above 1000° C. The radiant heating can be quickly turned on and off to controllably heat the wafer over a relatively short period, for example, of one minute or, for example, 30 seconds, more specifically, 10 seconds, and even more specifically, one second. Temperature changes in RTP chambers are capable of occurring at rates of at least about 25° C. per second to 50° C. per second and higher, for example at least about 100° C. per second or at least about 150° C. per second. The RTP chamber may be pressurized by flowing an inert gas into the chamber until the chamber reaches a total pressure greater than about 1.5 atmospheres absolute or, optionally, 2 atmospheres absolute. The substrate is processed under these hyperbaric conditions.

The method of some embodiments pressurizes the hyperbaric RTP chamber to greater than about 1.5 atmospheres absolute or, optionally, 2 atmospheres absolute, and in particular, greater than about 5 atmospheres absolute. In specific embodiments, the hyperbaric RTP chamber is pressurized between about 1.5 atmospheres absolute or, optionally, 2 atmospheres absolute and about 5 atmospheres absolute. In more specific embodiments, the method includes pressurizing the chamber to an absolute pressure exceeding 1.5 atmospheres, exceeding 2 atmospheres, exceeding 2.5 atmospheres, exceeding 3 atmospheres, exceeding 3.5 atmospheres, exceeding 4 atmospheres, exceeding 4.5 atmospheres and up to and in excess of 5 atmospheres. In other detailed embodiments have the hyperbaric RTP chamber is pressurized between about 2 atmospheres absolute and about 10 atmospheres absolute. According to one or more embodiments of the invention, the processing comprises rapid thermal annealing of a semiconductor wafer, for example, a silicon wafer.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of processing a substrate in a rapid thermal processing chamber, comprising:
passing a substrate from outside the rapid thermal processing chamber through an access port onto an annular support located in an interior region of the processing chamber;
closing the access port so that the rapid thermal processing chamber is sealed; pressurizing the rapid thermal processing chamber to a pressure greater than about 1.5 atmospheres absolute; and
directing radiant energy towards the substrate to controllably and uniformly heat the substrate at a rate of at least about 50° C. per/second.

2. The method of claim 1, wherein the rapid thermal processing chamber is pressurized to an absolute pressure in the range of about 2 atmospheres to about 5 atmospheres.

3. The method of claim 1, wherein the rapid thermal processing chamber is pressurized to an absolute pressure about up to about 3.0 atmospheres.

4. The method of claim 1, wherein the rapid thermal processing chamber is pressurized to an absolute pressure up to about 3.5 atmospheres.

5. The method of claim 1, wherein the rapid thermal processing chamber is pressurized to an absolute pressure up to about 4.0 atmospheres.

6. The method of claim 1, wherein the rapid thermal processing chamber is pressurized to an absolute pressure up to about 4.5 atmospheres.

7. The method of claim 1, wherein the substrate comprises a semiconductor wafer and the processing comprises rapid thermal annealing of the semiconductor wafer.

8. The method of claim 1, wherein the chamber further comprises a radiant heat source and a disc shaped surface between the chamber and radiant heat source, the disc shaped surface constructed to withstand at least about 2 atmospheres of absolute pressure.

9. The method of claim 8, wherein the disc shaped surface is constructed to withstand pressures in the range of about 2 atmospheres absolute to about 5 atmospheres absolute.

10. The method of claim 1, wherein the chamber further comprises a reflector plate located opposite the radiant heat source, the reflector plate constructed to withstand at least 2 atmospheres of absolute pressure.

11. The method of claim 10, wherein the reflector plate is constructed to withstand pressures up to about 5 atmospheres absolute.

12. The method of claim 1, wherein substrate is a semiconductor wafer, and the processing comprises rapid thermal annealing of the semiconductor wafer.

13. A rapid thermal processing chamber, comprising:
a chamber body defining a chamber volume;
a substrate support for supporting a substrate to be thermally processed within the chamber;
a first heat source configured for heating the substrate; and
a pressure control valve to control pressure within the chamber in excess of 2 atmospheres absolute.

14. The chamber of claim 13 wherein the pressure control valve is operative to control pressure within the chamber in the range of about 2 atmospheres absolute to about 5 atmospheres absolute.

15. The chamber of claim 13, wherein the pressure control valve is operative to control pressure within the chamber up to 3.5 atmospheres absolute.

16. The chamber of claim 13, wherein the pressure control valve is operative to control pressure within the chamber up to about 4.0 atmospheres absolute.

17. The chamber of claim 13, wherein the pressure control valve is operative to control pressure within the chamber up to about 4.5 atmospheres absolute.

18. The chamber of claim 13 wherein the chamber is a cold wall reactor type.

19. The chamber of claim 13, wherein the substrate support is magnetically coupled to a stator.

20. The chamber of claim 13, wherein the pressure control valve comprises a back pressure regulator and a pressure controller.
